(19) United States
(12) Patent Application Publication
(10) Pub. No.: US 2018/0328999 A1
(43) Pub. Date: Nov. 15, 2018

(54) POWER SUPPLY MONITORING DEVICE, STORAGE APPARATUS, AND POWER SUPPLY MONITORING METHOD

(71) Applicant: FUJITSU LIMITED, Kawasaki-shi (JP)

(72) Inventors: Hiroki TASHIMA, Yokohama (JP); Kentarou Yuasa, Chofu (JP)

(73) Assignee: FUJITSU LIMITED, Kawasaki-shi (JP)

(21) Appl. No.: 15/976,083

(22) Filed: May 10, 2018

(30) Foreign Application Priority Data
May 15, 2017 (JP) 2017-096820

(51) Int. Cl. G01R 31/42

(52) U.S. Cl. CPC G01R 31/42

(57) ABSTRACT

An apparatus receives an abnormality occurrence notification from an abnormality source power supply unit that is one of a plurality of power supply units each including a second processor and coupled to one of a plurality of external power supplies. Upon reception of an abnormality occurrence notification from a specific power supply unit, the apparatus acquires input voltages of other power supply units coupled to a specific external power supply coupled to the specific power supply unit and perform a first determination of whether a failure has occurred at the specific power supply unit based on the input voltages of the other power supply units and abnormality occurrence notifications received from the other power supply units, and makes a notification about a result of the first determination.

### CROSS-REFERENCE TO RELATED APPLICATION

This application is based upon and claims the benefit of priority of the prior Japanese Patent Application No. 2017-96820, filed on May 15, 2017, the entire contents of which are incorporated herein by reference.

### FIELD

The embodiment discussed herein is related to a power supply monitoring device, a storage apparatus, and a power supply monitoring method.

### BACKGROUND

With a recent tendency of digitizing various types of data for their use on computers, the amount of data handled by corporations has continuously grown every year. Each corporation may put a data center in charge of the management of massive amounts of data. In such a data center, many information and communication technology (ICT) devices, such as a server and a disk array device, are disposed. Power supplied to these devices and power for cooling these devices are steadily increased. In the data center, a large power fluctuation occurs depending on the ON/OFF state of a power supply for a system and the operational status of the system. This may cause the fluctuations in the voltage and frequency of an input power supply, an instantaneous power interruption, noise, or a distortion.

A storage apparatus having a redundant arrays of inexpensive disks (RAID) configuration includes enclosures with different functions, a controller enclosure and a disk enclosure. The disk enclosure incorporates a storage such as a hard disk for storing data. The controller enclosure has a function of controlling the reading/writing of data from/into the disk enclosure, for example, the writing of data transmitted from a host into a drive enclosure. A storage apparatus usually includes a plurality of disk enclosures. The controller enclosure includes a controller module (CM) including a central processing unit (CPU), a channel adapter (CA), and a cache and a battery backup unit (BBU). Both of the controller enclosure and the disk enclosure include respective power supply units (PSUs).

For the achievement of redundancy, each of the controller enclosure and the disk enclosure includes a redundant PSU. For example, a single storage apparatus includes several to several hundred PSUs. A storage apparatus has a function of saving data remaining in its cache in a nonvolatile memory at the time of occurrence of a power interruption. Each PSU therefore includes a circuit for detecting a power interruption. Each PSU is designed to enable a power interruption detection signal and withstand an instantaneous input abnormality for approximately several milliseconds in a case where it is difficult for the PSU to maintain an output. For example, each PSU includes an output compensation capacitor to maintain an output at the time of occurrence of an instantaneous power abnormality.

As conditions where a failure occurs in a storage apparatus, the following two exemplary cases are considered. A first case is that a plurality of PSUs detect a power interruption at the same time when a power supply abnormality occurs at an external power supply that is a power supply input source of the storage apparatus. At that time, respective PSUs in a controller enclosure and a disk enclosure connected to the external power supply at which the failure occurs detect a power interruption. Since a plurality of PSUs detect the power interruption, it can be determined that the abnormality has occurred at the external power supply.

The second case is that one of PSUs included in a controller enclosure and a disk enclosure detects a power interruption. The following two causes of this case are considered. One of these causes is the fault of a PSU. That is, a fault occurs at a power interruption detection circuit in the PSU and the PSU incorrectly detects the power interruption.

The other one of these causes is the occurrence of a temporary abnormality at the external power supply. In a case where a temporary abnormality has occurred at the external power supply, it is considered that some of PSUs connected to the external power supply detect the power interruption because of variations in power interruption detection accuracy among the PSUs. For example, in a case where only one of the PSUs has detected the power interruption, the cause of this situation is considered to be the fault of the power interruption detection circuit in the PSU or the occurrence of a temporary abnormality at the external power supply. In both of these cases, the PSU is usually replaced for the sake of a stable operation of an apparatus.

There is a known technique for detecting an instantaneous interruption when detecting a state where an input from an alternating current (AC) power supply is instantaneously below a threshold value a plurality of times (Japanese Laid-open Patent Publication No. 2004-206367). As a technique for making a structure for supplying power to a disk drive redundant, there is a known technique for making a direct current (DC)/DC converter redundant (Japanese Laid-open Patent Publication No. 2008-193876).

### SUMMARY

According to an aspect of the invention, an apparatus receives an abnormality occurrence notification from an abnormality source power supply unit that is one of a plurality of power supply units each including a second processor and coupled to one of a plurality of external power supplies. Upon reception of an abnormality occurrence notification from a specific power supply unit, the apparatus acquires input voltages of other power supply units coupled to a specific external power supply coupled to the specific power supply unit and perform a first determination of whether a failure has occurred at the specific power supply unit based on the input voltages of the other power supply units and abnormality occurrence notifications received from the other power supply units, and makes a notification about a result of the first determination.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a power supply flow in a storage apparatus according to an embodiment;

FIG. 2 is a diagram illustrating a signal flow in a storage apparatus according to an embodiment;

FIG. 3 is a diagram illustrating the configuration of a PSU according to an embodiment;

FIG. 4 is a diagram illustrating the exemplary sampling of input voltages;

FIG. 5 is a diagram illustrating exemplary failures at an external power supply;

FIG. 6 is a block diagram illustrating the failure isolation function of a CM;

FIG. 7 is a diagram describing an input voltage abnormality; and

FIG. 8 is a flowchart illustrating a failure isolation process performed by a storage apparatus according to an embodiment.

### DESCRIPTION OF EMBODIMENT

In a case where one of PSUs detects a power interruption and the PSU is replaced, the replacement can remove a suspicious part and leads to the stable operation of a storage apparatus on condition that the cause of this situation is a fault in the PSU. By investigating the replaced PSU, a fault part can be specified. However, in a case where the cause is a temporary abnormality at the external power supply, a suspicious part is not removed even after the PSU has been replaced and a PSU may make a power interruption notification again. The investigation, discarding, and the like of the replaced normal PSU waste time and cost. Thus, it is difficult to determine which of the temporary abnormality at the external power supply and the fault in the PSU is the cause of the situation and increase the efficiency of a maintenance operation at the time of the occurrence of a failure with known methods.

It is also difficult to determine which of the temporary abnormality at the external power supply and the fault in the PSU is the cause of the situation and increase the efficiency of a maintenance operation at the time of the occurrence of a failure with the known technique for detecting an instantaneous interruption when detecting a state where an input is instantaneously below a threshold value a plurality of times. The known technique for making a DC/DC converter redundant does not take the detection of a power interruption by a PSU into consideration, and it is therefore difficult to increase the efficiency of a maintenance operation at the time of the occurrence of a failure with this known technique.

It is an object of the present disclosure to provide a power supply monitoring device, a storage apparatus, and a power supply monitoring method which increase the efficiency of a maintenance operation at the time of occurrence of a failure.

A power supply monitoring device according to an embodiment, a storage apparatus according to an embodiment, and a power supply monitoring method according to an embodiment will be described in detail below with reference to the accompanying drawings. A power supply monitoring device, a storage apparatus, and a power supply monitoring method are not limited to an embodiment to be described below.

### Embodiment

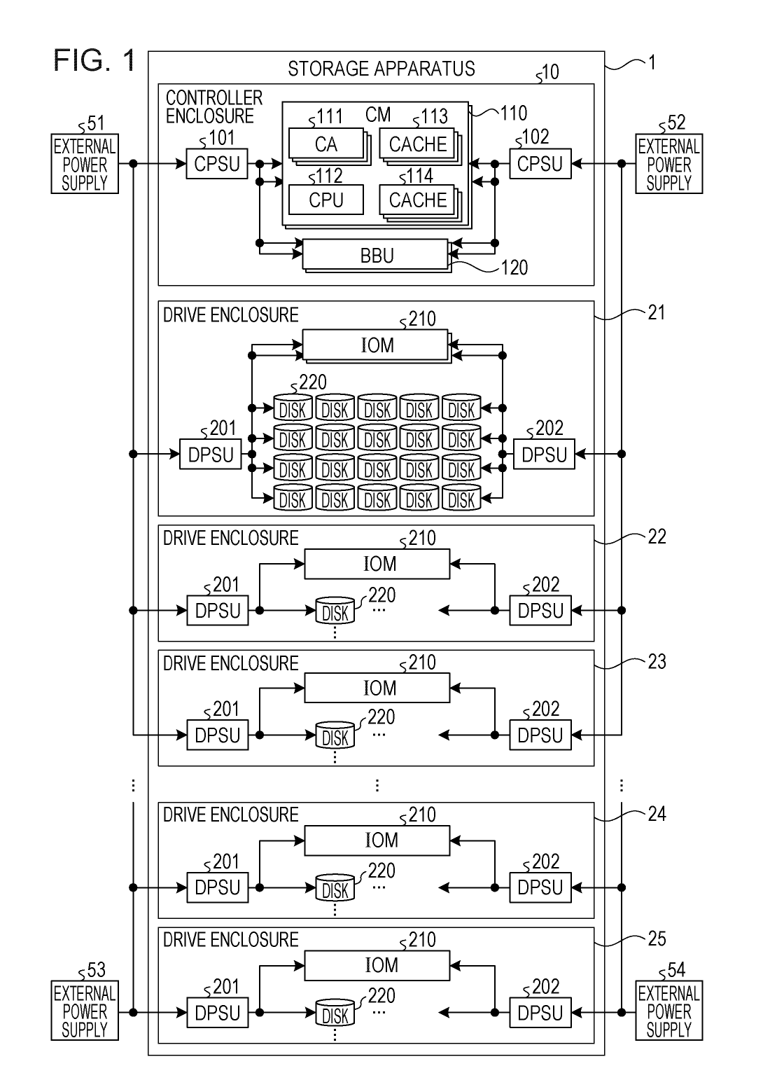

FIG. 1 is a diagram illustrating a power supply flow in a storage apparatus according to an embodiment. As illustrated in FIG. 1, a storage apparatus 1 includes a controller enclosure 10 and drive enclosures 21 to 25. External power supplies 51 to 54 are commercial power supplies or another type of secondary batteries.

In the controller enclosure 10, a controller enclosure PSUs (CPSUs) 101 and 102, a controller module (CM) 110, and a BBU 120 are installed. The number of the controller enclosures 10 is one in FIG. 1, but may be one or more.

In the drive enclosure 21, drive enclosure PSUs (DPSUs) 201 and 202, an input output module (IOM) 210, and a plurality of disks 220 are installed. The drive enclosures 22 to 25 have the same configuration as the drive enclosure 21. The number of the disks 220 may vary in the drive enclosures 21 to 25. The disks 220 may have different logical storage configurations and RAID configurations.

The CPSUs 101 and 102 operate as a redundant power supply unit. The DPSUs 201 and 202 in each of the drive enclosures 21 to 25 operate as a redundant power supply unit.

The CPSU 101 and the DPSUs 201 in the drive enclosures 21 to 23 are connected to an external power supply 51 to receive power supplied from the external power supply 51. The DPSUs 201 in the drive enclosures 24 and 25 are connected to the external power supply 53 that is, for example, a commercial power supply to receive power supplied from the external power supply 51.

The CPSU 102 and the DPSUs 202 in the drive enclosures 21 to 23 are connected to the external power supply 52 that is, for example, a commercial power supply to receive power supplied from the external power supply 52. The DPSUs 202 in the drive enclosures 24 and 25 are connected to the external power supply 54 that is, for example, a commercial power supply to receive power supplied from the external power supply 54. Although the external power supplies 51 to 54 are illustrated, other external power supplies are provided in reality and are each connected to the DPSUs 201 (not illustrated) or the DPSUs 202 (not illustrated).

The CPSUs 101 and 102 supply power input from the external power supplies 51 and 52 to the CM 110 and the BBU 120. The CM 110 and the BBU 120 operate with power supplied from the CPSUs 101 and 102. There are the multiple CMs 110 and the multiple BBUs 120.

The BBU 120 is a backup battery. In a case where a power interruption occurs and the supply of power stops, the BBU 120 supply power to allow a CPU 112 to save contents of a cache 113.

In this embodiment, there are the multiple CMs 110 for the achievement of redundancy. However, the number of the CMs 110 may be one. The CM 110 includes a CA 111, the CPU 112, the cache 113, and a cache 114. In this embodiment, there are the multiple CAs 111, the multiple caches 113, and the multiple caches 114 for the achievement of redundancy. The CA 111, the CPU 112, and the caches 113 and 114 in the CM 110 operate with power supplied from the CPSUs 101 and 102. The CM 110 corresponds to examples of a “control device” and a “power supply monitoring device”.

In this embodiment, there are the multiple BBUs 120 for the achievement of redundancy. However, the number of the BBUs 120 may be one. The BBU 120 operate with power supplied from the CPSUs 101 and 102.

The DPSUs 201 and 202 supply power input from the external power supplies 51 to 54 to the IOMs 210 and the disks 220. The IOMs 210 and the disks 220 operate with power supplied from the DPSUs 201 and 202.

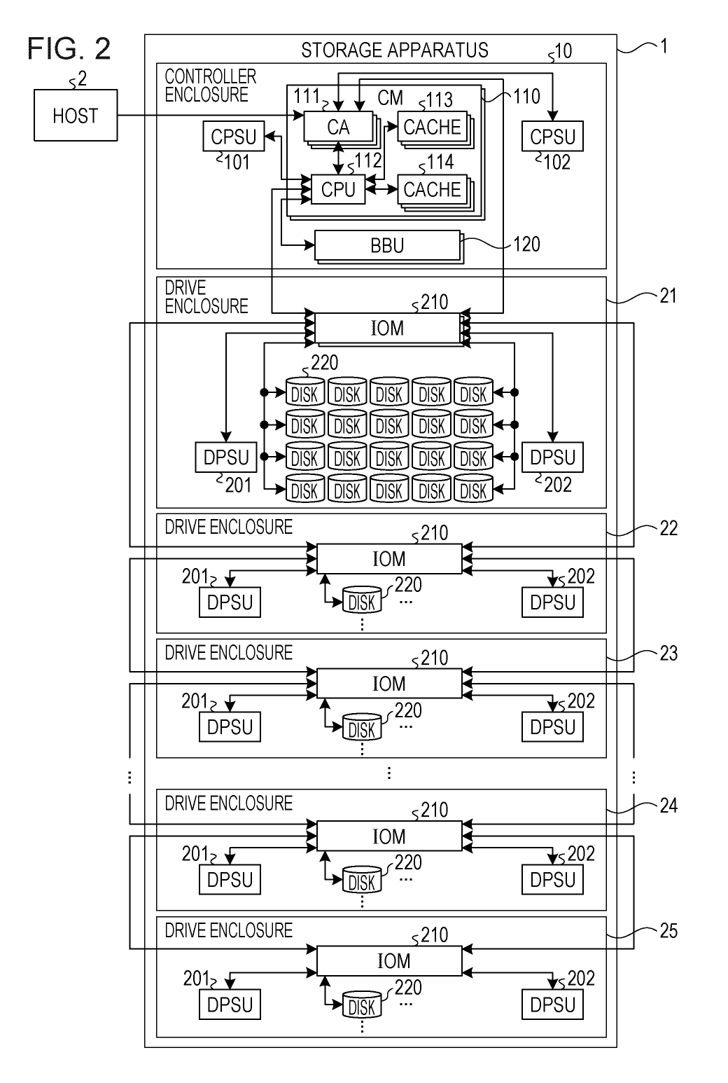

FIG. 2 is a diagram illustrating a signal flow in a storage apparatus according to an embodiment. The storage apparatus 1 is connected to a host 2 that is a computation processing apparatus.

The caches 113 and 114 are temporary storages each including a random access memory (RAM).

The CA 111 is a repeater that transfers input information to a destination. The CA 111 receives an instruction for reading/writing data from/into the disks 220 from the host 2. The CA 111 outputs the received reading/writing instruction to the CPU 112.

In the case of the reading instruction, the CA 111 receives from the CPU 112 an request for the reading of specified data from the disk 220 when the specified data is not stored in the cache 113 or 114. The CA 111 receives from the IOM 210 data read from the disk 220, and transmits the acquired data to the CPU 112.

The CA 111 receives from the CPU 112 data specified by the reading instruction and transmits the acquired data to the host 2.

In the case of the writing instruction, the CA 111 receives a data writing request from the CPU 112 and outputs the data writing request to the IOM 210. Subsequently, the CA 111 receives a data writing completion notification from the IOM 210 and outputs the data writing completion notification input from the IOM 210 to the CPU 112. Subsequently, the CA 111 receives a writing completion notification from the CPU 112 and notifies the host 2 of the completion of writing.

The CPU 112 receives from the CA 111 the reading instruction and the writing instruction transmitted from the host 2. In the case of the reading instruction, the CPU 112 determines whether the specified data is stored in the cache 113 or 114. In a case where the specified data is stored in the cache 113 or 114, the CPU 112 reads the data from the cache 113 or 114 and outputs the read data to the CA 111.

In a case where the specified data is not stored in the cache 113 or 114, the CPU 112 requests the CA 111 to read the specified data from the disk 220. Subsequently, the CPU 112 receives from the CA 111 data read from the disk 220. The CPU 112 writes the acquired data into the cache 113 or 114 and transmits the acquired data to the host 2 via the CA 111.

In the case of the writing instruction, the CPU 112 outputs the data writing request transmitted from the host 2 to the IOM 210. Subsequently, the CPU 112 receives from the CA 111 the writing completion notification transmitted from the IOM 210. The CPU 112 outputs the writing completion notification to the CA 111.

The CPU 112 communicates with the BBU 120 to check a battery capacity and detect an abnormality. The CPU 112 communicates with the CPSU 101 to perform the detection of a power supply abnormality at the controller enclosure 10, for example, the detection of a power interruption or the detection of occurrence of a failure at the CPSU 101. The CPU 112 communicates with the DPSUs 201 and 202 in the drive enclosures 21 to 25 via the CA 111 and the IOMs 210 to perform the detection of a power supply abnormality at the drive enclosures 21 to 25, for example, the detection of a power interruption or the detection of occurrence of a failure at the DPSU 201 or 202. Failure isolation based on the detection of a power supply abnormality at the controller enclosure 10 and the drive enclosures 21 to 25 will be described in detail below.

The IOMs 210 are control mechanisms for passing data between the drive enclosures 21 to 25 and the CPU 112 in the CM 110. The respective IOMs 210 in the drive enclosures 21 to 25 are connected in a daisy chain. Descriptions will be made below under the assumption that the respective IOMs 210 in the drive enclosures 21 to 25 directly transmit/receive data to/from the CPU 112. However, in reality, one or some of the IOMs 210 are connected to the CPU 112 via another IOM 210 in reality.

The IOM 210 receives a data reading request from the CPU 112. The IOM 210 reads specified data from the disk 220 and outputs the read data to the CA 111.

The IOM 210 receives a data writing request from the CPU 112. The IOM 210 writes specified data into the disk 220 and outputs a writing completion notification to the CA 111.

In the detection of a power supply abnormality at each of the drive enclosures 21 to 25, the IOM 210 relays communication between each of the DPSUs 201 and 202 and the CPU 112.

The disk 220 is an auxiliary storage such as a hard disk. For example, the disks 220 constitute a RAID.

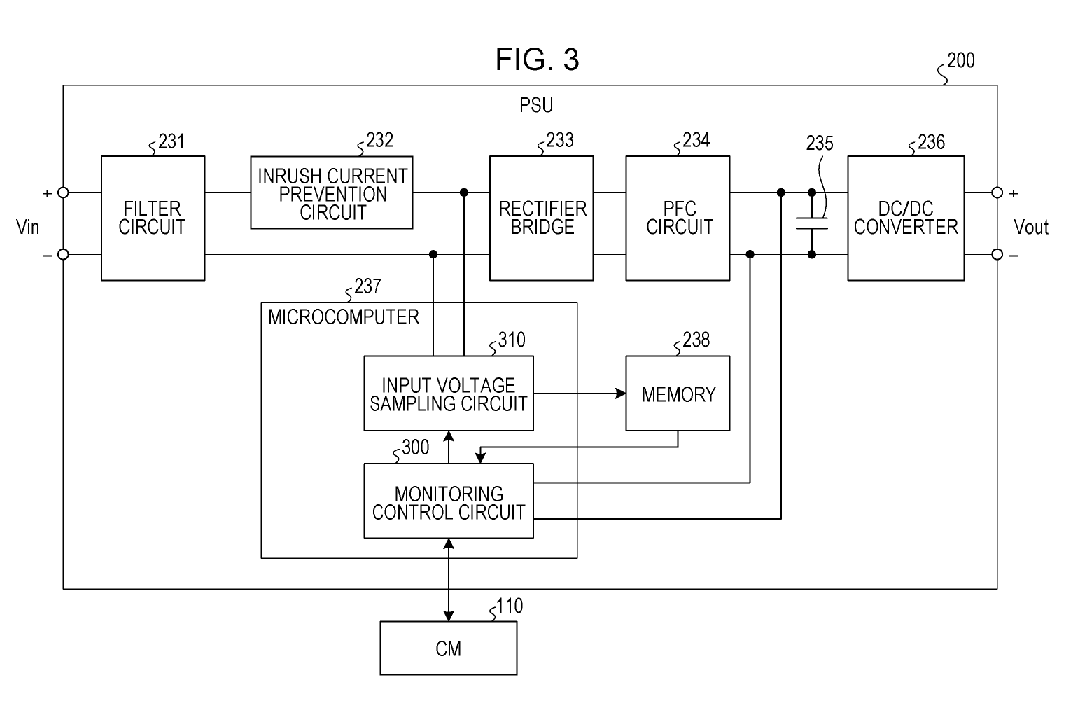

Next, the CPSUs 101 and 102, and the DPSUs 201 and 202 will be described. The CPSUs 101 and 102 and the DPSUs 201 and 202 correspond to an example of a “power supply unit”. Since the CPSUs 101 and 102, and the DPSUs 201 and 202 have the same configuration, each of them is sometimes referred to as a “PSU 200” in a case where they are not distinguished from one another. FIG. 3 is a diagram illustrating the configuration of a PSU according to an embodiment. In this example, the PSU 200 receives power from the external power supply 51.

The PSU 200 includes a filter circuit 231, an inrush current prevention circuit 232, a rectifier bridge 233 a power factor correction (PFC) circuit 234, an output compensation capacitor 235, and a DC/DC converter 236. Two paths, positive and negative power supply paths, are connected to the filter circuit 231, the inrush current prevention circuit 232, the rectifier bridge 233, the PFC circuit 234, the output compensation capacitor 235, and the DC/DC converter 236. The PSU 200 further includes a microcomputer 237 and a memory 238.

The filter circuit 231 receives electricity supplied from the external power supply 51. The filter circuit 231 removes noise from input electricity and outputs the electricity from which noise has been removed to the rectifier bridge 233.

The inrush current prevention circuit 232 is disposed between the filter circuit 231 and the rectifier bridge 233. The inrush current prevention circuit 232 smooths a current value in the rise of electricity output from the filter circuit 231 on the side of the positive power supply by providing a delay with a relay.

The rectifier bridge 233 receives electricity from the filter circuit 231 via the inrush current prevention circuit 232, rectifies AC electricity to DC electricity, and outputs the DC electricity to the PFC circuit 234.

The PFC circuit 234 receives electricity from the rectifier bridge 233. The PFC circuit 234 is a power-factor improvement circuit, and improves the power factor of the input electricity to shape a voltage waveform. The PFC circuit 234 outputs the electricity whose power factor has been improved to the DC/DC converter 236.

The output compensation capacitor 235 is disposed between the PFC circuit 234 and the DC/DC converter 236, and stores electric charges. In a case where a voltage input from the PFC circuit 234 to the DC/DC converter 236 decreases, the output compensation capacitor 235 outputs compensation electricity to the DC/DC converter 236. As a result, the PSU 200 can maintain an output even if an instantaneous input abnormality occurs.

The DC/DC converter 236 has an output terminal. For example, the DC/DC converter 236 has a 12V power supply output terminal and a terminal connected to a signal grand (SG). The DC/DC converter 236 receives electricity from the PFC circuit 234 and the output compensation capacitor 235. The DC/DC converter 236 steps down input electricity. For example, the DC/DC converter 236 receives electricity of 400 V from the PFC circuit 234 and steps down the voltage to 12 V. The DC/DC converter 236 outputs the stepped-down electricity to the CM 110 or the disk 220.

Each of the rectifier bridge 233, the PFC circuit 234, the output compensation capacitor 235, and the DC/DC converter 236 may have a configuration different from the configuration illustrated in FIG. 3. The PSU 200 may include an AC/AC converter for rectifying an AC power supply to a DC power supply and performing rectification and a DC/DC converter for converting a DC power supply voltage into an output voltage and performing rectification.

The memory 238 is formed of, for example, read-only memory (ROM). The memory 238 has a storage region for storing input voltage information.

The microcomputer 237 monitors and controls an input voltage, and includes a monitoring control circuit 300 and an input voltage sampling circuit 310.

The input voltage sampling circuit 310 is connected to positive and negative power supply paths between the filter circuit 231 and the rectifier bridge 233. The input voltage sampling circuit 310 may measure a voltage at another place at which the change in an input voltage can be measured. For example, the input voltage sampling circuit 310 may be disposed between the rectifier bridge 233 and the PFC circuit 234.

The input voltage sampling circuit 310 measures the voltage of electricity input into the AD port of the microcomputer 237 at predetermined intervals to acquire measurement values, thereby performing the sampling of input voltages. The input voltage sampling circuit 310 stores input voltage information acquired for a predetermined period in a buffer thereof. For example, the input voltage sampling circuit 310 performs sampling at intervals of 0.5 milliseconds. The input voltage sampling circuit 310 stores input voltage information acquired for 5 seconds. That is, in this case, the input voltage sampling circuit 310 stores input voltage information acquired by 2,000 times/second×5 seconds. In a case where the input voltage sampling circuit 310 acquires new input voltage information, the input voltage sampling circuit 310 performs updating by overwriting stored information with new information.

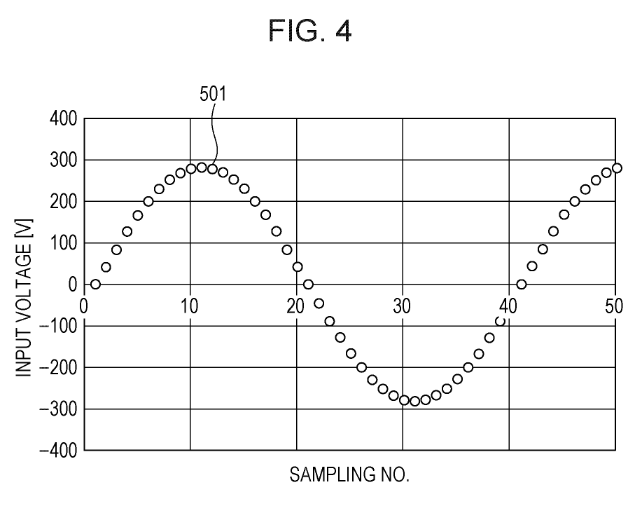

FIG. 4 is a diagram illustrating the exemplary sampling of input voltages. In FIG. 4, a vertical axis represents an input voltage and a horizontal axis represents a sampling number that is assigned to an acquired input voltage. The larger the sampling number, the older the input voltage information. The input voltage sampling circuit 310 assigns a sampling number of 1 to newly acquired input voltage information, increments the sampling number of stored input voltage information by one, and discards the oldest input voltage information. As a result, the input voltage sampling circuit 310 stores input voltage information representing the change in voltage for a predetermined period which is indicated by a graph 501 in FIG. 4.

The input voltage sampling circuit 310 receives an instruction for storing input voltage information in the storage region from the monitoring control circuit 300. The input voltage sampling circuit 310 stores input voltage information acquired for a predetermined period from the receipt of the instruction in the storage region in the memory 238.

The monitoring control circuit 300 measures the voltages of positive and negative power supply paths between the PFC circuit 234 and the output compensation capacitor 235 to acquire an internal voltage. The monitoring control circuit 300 determines whether the acquired internal voltage has fallen below an abnormality determination threshold value set in advance. For example, the monitoring control circuit 300 may determine that the internal voltage has fallen below the abnormality determination threshold value in a case where the internal voltage has fallen below the abnormality determination threshold value for several milliseconds. In a case where the internal voltage has fallen below the abnormality determination threshold value, the monitoring control circuit 300 outputs a power interruption detection signal to the CM 110. The monitoring control circuit 300 also instructs the input voltage sampling circuit 310 to store the input voltage information in the storage region.

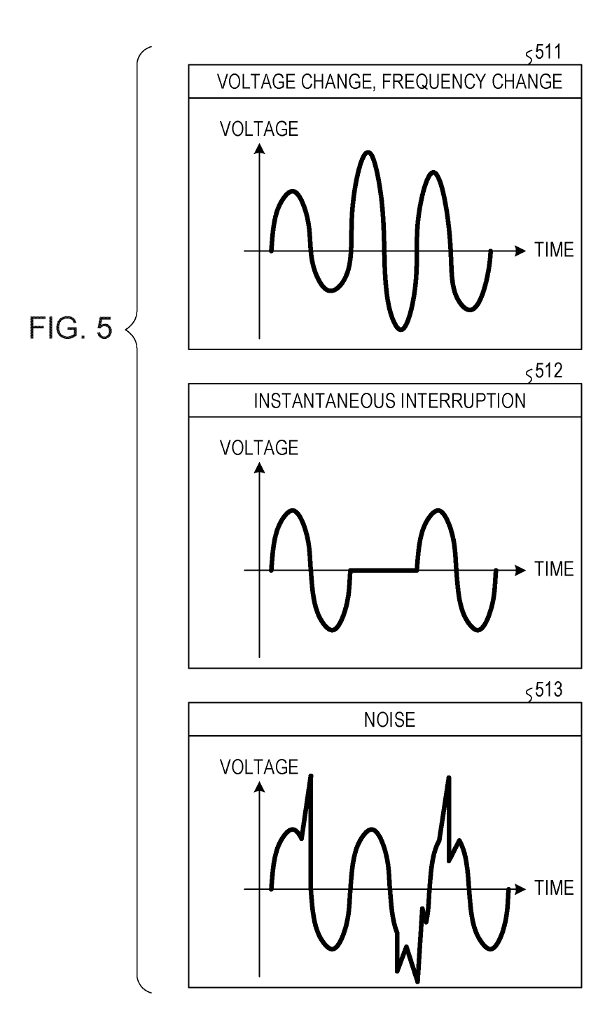

Here, an exemplary case where the monitoring control circuit 300 transmits a power interruption detection signal in response to the occurrence of a failure other than a power interruption will be described using the DPSU 201 connected to the external power supply 51. FIG. 5 is a diagram illustrating exemplary failures at an external power supply.

As illustrated in FIG. 5, a voltage input from the external power supply 51 variously changes because of a failure at the external power supply 51. For example, a graph 511 indicates a case where a voltage change or a frequency change occurs in a voltage input from the external power supply 51. In the graph 511, a vertical axis represents a voltage and a horizontal axis represents a time. A graph 512 indices a case where an instantaneous interruption occurs in a voltage input from the external power supply 51. Also in the graph 512, a vertical axis represents a voltage and a horizontal axis represents a time. A graph 513 indicates a case where noise occurs in a voltage input from the external power supply 51. Also in the graph 513, a vertical axis represents a voltage and a horizontal axis represents a time.

The voltage changes indicated by the graphs 511 to 513 are not steady power interruptions at the external power supply 51. However, the monitoring control circuit 300 in the DPSU 201 sometimes determines that an internal voltage has fallen below the abnormality determination threshold value at the time of occurrence of a transient voltage change indicated by each of the graphs 511 to 513. In this case, the monitoring control circuit 300 in the DPSU 201 outputs a power interruption detection signal despite the fact that the external power supply 51 is not subjected to a steady power interruption.

The monitoring control circuit 300 receives an instruction for storing input voltage information in the storage region from the CM 110 in a case where a power interruption detection signal has output from another PSU 200 configured to receive electricity from the external power supply 51. The monitoring control circuit 300 instructs the input voltage sampling circuit 310 to store the input voltage information in the storage region.

After making the instruction for storing the input voltage information in the storage region, the monitoring control circuit 300 receives an input voltage information transmission request from the CM 110. The monitoring control circuit 300 outputs input voltage information acquired for a predetermined period from the memory 238 to the CM 110. The monitoring control circuit 300 corresponds to an example of an “abnormality notification portion”.

Next, a function of detecting in the CM 110 a power supply abnormality at the controller enclosure 10 and the drive enclosures 21 to 25 will be described. The function to be described below is performed by, for example, the CPU 112 illustrated in FIG. 2.

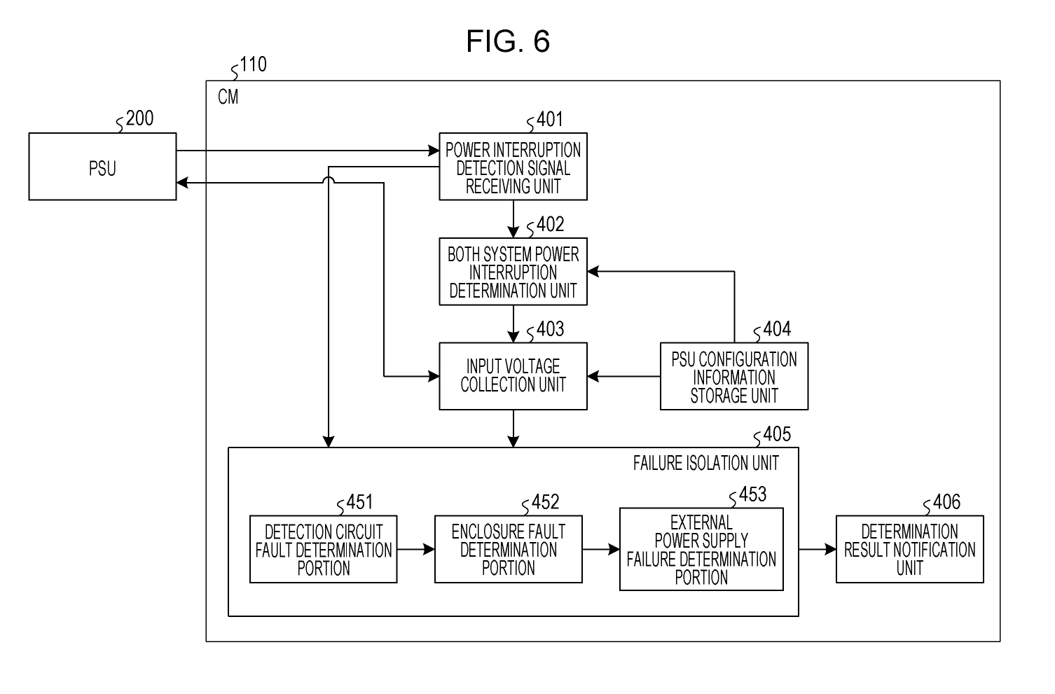

FIG. 6 is a block diagram illustrating the failure isolation function of a CM. As illustrated in FIG. 6, the CM 110 includes a power interruption detection signal receiving unit 401, a both system power interruption determination unit 402, an input voltage collection unit 403, a PSU configuration information storage unit 404, a failure isolation unit 405, and a determination result notification unit 406.

The PSU configuration information storage unit 404 stores PSU configuration information including information about the external power supplies 51 to 54 connected to the PSUs 200 and information about the controller enclosure 10 or the drive enclosures 21 to 25 in which the PSU 200 is installed which have been input in advance. For example, in the case of the storage apparatus 1 illustrated in FIG. 1, the PSU configuration information storage unit 404 stores the fact that the CPSU 101 installed in the controller enclosure 10 and the DPSUs 201 installed in the drive enclosures 21 to 23 have been connected to the external power supply 51. The PSU configuration information storage unit 404 also stores the fact that the CPSU 102 installed in the controller enclosure 10 and the DPSUs 202 installed in the drive enclosures 21 to 23 have been connected to the external power supply 52. The PSU configuration information storage unit 404 also stores the fact that the DPSUs 201 installed in the drive enclosures 24 and 25 have been connected to the external power supply 53. The PSU configuration information storage unit 404 also stores the fact that the DPSUs 202 installed in the drive enclosures 24 and 25 have been connected to the external power supply 54.

The power interruption detection signal receiving unit 401 receives a power interruption detection signal output from the monitoring control circuit 300 in the PSU 200. A case where the power interruption detection signal receiving unit 401 has received a power interruption detection signal from the DPSU 201 in the drive enclosure 22 will be described. The PSU 200 that is the transmission source of a power interruption detection signal is hereinafter referred to as a “failure source PSU”. The power interruption detection signal receiving unit 401 corresponds to an example of a “receiving unit”. The DPSU 201 in the drive enclosure 22 that is a failure source PSU from which a power interruption detection signal has been transmitted corresponds to an example of a “specific power supply unit”.

As described above, even though a power interruption detection signal has been received from the DPSU 201 in the drive enclosure 22 which is a failure source PSU, a power interruption has not necessarily occurred at the external power supply 51 connected to the DPSU 201. The CM 110 therefore determines whether a power interruption has occurred at the external power supply 51 or another failure has occurred by performing the following process. The power interruption detection signal receiving unit 401 outputs information about the PSU 200 that is the transmission source of the power interruption detection signal to the both system power interruption determination unit 402 and the failure isolation unit 405.

The both system power interruption determination unit 402 receives the information about the DPSU 201 in the drive enclosure 22, which is a failure source PSU, from the power interruption detection signal receiving unit 401. The both system power interruption determination unit 402 specifies the PSU 200 installed in the same enclosure as the PSU 200 that is the transmission source of the power interruption detection signal using PSU configuration information stored in the PSU configuration information storage unit 404. The PSU 200 installed in the same enclosure as the failure source PSU is hereinafter referred to as an “enclosure sharing PSU”. In this case, the both system power interruption determination unit 402 specifies the DPSU 202 installed in the drive enclosure 22 as the enclosure sharing PSU. The both system power interruption determination unit 402 determines whether information about the DPSU 202 in the drive enclosure 22, which is the enclosure sharing PSU, has been input from the power interruption detection signal receiving unit 401 and determines whether the DPSU 202 in the drive enclosure 22 has output the power interruption detection signal based on a result of the determination. The fact of whether the PSU 200 has output the power interruption detection signal is hereinafter sometimes referred to as the “power interruption detection signal status” of the PSU 200.

In a case where the power interruption detection signal has been transmitted from the DPSU 202 in the drive enclosure 22 which is the enclosure sharing PSU, the both system power interruption determination unit 402 determines that a both system power interruption has occurred. The both system power interruption determination unit 402 performs power interruption processing for saving data stored in the caches 113 and 114 into the disk 220. Subsequently, the both system power interruption determination unit 402 shuts down the storage apparatus 1.

On the other hand, in a case where the power interruption detection signal has not been transmitted from the DPSU 202 in the drive enclosure 22 which is the enclosure sharing PSU, the both system power interruption determination unit 402 notifies the input voltage collection unit 403 of information about the failure source PSU and the occurrence of a failure other than the both system power interruption. The both system power interruption determination unit 402 also outputs information about the enclosure sharing PSU to the input voltage collection unit 403.

The input voltage collection unit 403 is notified by the both system power interruption determination unit 402 of the information about the failure source PSU and the occurrence of a failure other than the both system power interruption. The input voltage collection unit 403 also receives the information about the enclosure sharing PSU from the both system power interruption determination unit 402.

The input voltage collection unit 403 specifies the PSU 200 connected to the same power supply as the failure source PSU, i.e., one of the external power supplies 51 to 54, using the PSU configuration information stored in the PSU configuration information storage unit 404. The PSU 200 connected to the same power supply as the failure source PSU is hereinafter referred to as an “external power supply sharing PSU”. In this case, the input voltage collection unit 403 specifies the CPSU 101 and the DPSUs 201 in the drive enclosures 21 and 23 as the external power supply sharing PSUs.

Subsequently, the input voltage collection unit 403 transmits an instruction for storing the input voltage information in the storage region to the external power supply sharing PSU and the enclosure sharing PSU. In this case, the input voltage collection unit 403 transmits the instruction for storing the input voltage information in the storage region to the CPSU 101, the DPSUs 201 in the drive enclosures 21 and 23, and the DPSU 202 in the drive enclosure 22.

Subsequently, the input voltage collection unit 403 requests the external power supply sharing PSU and the enclosure sharing PSU to transmit the input voltage information to acquire the input voltage information. That is, the input voltage collection unit 403 requests the CPSU 101, the DPSUs 201 in the drive enclosures 21 and 23, and the DPSU 202 in the drive enclosure 22 to transmit the input voltage information, and acquires the input voltage information acquired for a predetermined period from them. Subsequently, the input voltage collection unit 403 outputs the pieces input voltage information acquired for a predetermined period, which have been acquired from the CPSU 101, the DPSUs 201 in the drive enclosures 21 and 23, and the DPSU 202 in the drive enclosure 22, to the failure isolation unit 405.

The input voltage collection unit 403 also requests the DPSU 201 in the drive enclosure 22, which is the failure source PSU, to transmit the input voltage information to acquire the input voltage information.

The failure isolation unit 405 checks the power interruption detection signal status of the receiving units in the enclosure sharing PSU and the external power supply sharing PSU based on the fact of whether it has received from the power interruption detection signal receiving unit 401 the power interruption detection signals transmitted from the enclosure sharing PSU and the external power supply sharing PSU.

The failure isolation unit 405 receives the pieces of input voltage information of the failure source PSU, the external power supply sharing PSU, and the enclosure sharing PSU. In this case, the failure isolation unit 405 receives the pieces of input voltage information that have been acquired by the CPSU 101, the DPSUs 201 and 202 in the drive enclosure 22, and the DPSUs 201 in the drive enclosures 21 and 23 for a predetermined period.

The failure isolation unit 405 includes a detection circuit fault determination portion 451, an enclosure fault determination portion 452, and an external power supply failure determination portion 453. The detection circuit fault determination portion 451, the enclosure fault determination portion 452, and the external power supply failure determination portion 453 determine different failure causes.

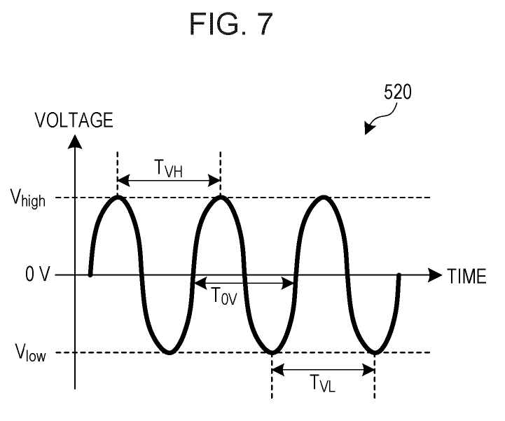

Upon receiving the input voltage information from the input voltage collection unit 403, the detection circuit fault determination portion 451 determines whether there is an abnormality in the input voltage information of the failure source PSU. An abnormality in the input voltage information will be described with reference to FIG. 7. FIG. 7 is a diagram describing an input voltage abnormality. In FIG. 7, a vertical axis represents a voltage and a horizontal axis represents a time.

The detection circuit fault determination portion 451 measures times taken for periodic voltages such as the maximum and minimum values and 0 V of the input voltage of the DPSU 201 in the drive enclosure 22, which is the failure source PSU, to appear. For example, the input voltage collection unit 403 acquires an input voltage maximum value cycle T_{VH}, an input voltage minimum value cycle T_{VA}, and an input voltage 0V cycle T_{0V} in a graph 520 in FIG. 7. The detection circuit fault determination portion 451 collects pieces of information about the input voltage maximum value cycle T_{VH}, the input voltage minimum value cycle T_{VA}, and the input voltage 0V cycle T_{0V} and checks whether there is a specific point in the input voltage of the failure source PSU. In a case where there is a specific point in the input voltage of the failure source PSU, the detection circuit fault determination portion 451 determines that an abnormality such as a voltage change, a frequency change, a voltage sag, an instantaneous interruption, or noise illustrated in FIG. 5 has occurred in the input voltage of the failure source PSU.

In a case where there is no abnormality in the input voltage information of the failure source PSU, the failure source PSU has output the power interruption detection signal despite the fact that the input voltage of the failure source PSU is normal. That is, the failure source PSU has output the power interruption detection signal despite the fact that the internal voltage is not below the abnormality determination threshold value in reality. The detection circuit fault determination portion 451 therefore determines that a fault has occurred at the power interruption detection circuit in the failure source PSU. The detection circuit fault determination portion 451 notifies the determination result notification unit 406 that a fault has occurred at the power interruption detection circuit in the failure source PSU. In this case, the detection circuit fault determination portion 451 determines that a fault has occurred at the power interruption detection circuit in the monitoring control circuit 300 in the DPSU 201 in the drive enclosure 22 and notifies the determination result notification unit 406 of a result of the determination.

On the other hand, in a case where there is an abnormality in the input voltage information of the failure source PSU, the detection circuit fault determination portion 451 notifies the enclosure fault determination portion 452 that the power interruption detection circuit in the failure source PSU is under normal conditions. The detection circuit fault determination portion 451 corresponds to an example of a “second determination unit”.

The enclosure fault determination portion 452 is notified by the detection circuit fault determination portion 451 that the power interruption detection circuit in the failure source PSU is under normal conditions. The enclosure fault determination portion 452 measures times taken for periodic voltages such as the maximum and minimum values and 0 V of the input voltage of the enclosure sharing PSU to appear. In this case, the enclosure fault determination portion 452 measures times taken for the periodic voltages of the DPSU 202 in the drive enclosure 22 to appear. In a case where there is a specific point in the input voltage of the enclosure sharing PSU, the enclosure fault determination portion 452 determines that an abnormality has occurred in the input voltage of the enclosure sharing PSU. The enclosure fault determination portion 452 also checks the power interruption detection signal status of the enclosure sharing PSU. The DPSU 202 in the drive enclosure 22 which is the enclosure sharing PSU corresponds to an example of a “redundant power supply unit”.

In a case where the enclosure sharing PSU has output the power interruption detection signal or there is an abnormality in the input voltage information of the enclosure sharing PSU, it can be said that an enclosure in which the failure source PSU is installed has detected a failure and the other enclosures have not detected a failure. That is, it can be said that an abnormality has occurred at the DPSUs 201 and 202 installed in the drive enclosure 22 despite the fact that a failure does not occur at the external power supply 51. The enclosure fault determination portion 452 therefore determines that a fault has occurred at the enclosure in which the failure source PSU is installed, that is, the drive enclosure 22. In this case, the enclosure fault determination portion 452 notifies the determination result notification unit 406 that a fault has occurred at the enclosure in which the failure source PSU is installed. In this case, the enclosure fault determination portion 452 notifies the determination result notification unit 406 that a fault has occurred at the drive enclosure 22.

On the other hand, in a case where the enclosure sharing PSU has not output the power interruption detection signal and there is no abnormality in the input voltage of the enclosure sharing PSU, the enclosure fault determination portion 452 notifies the external power supply failure determination portion 453 that the enclosure in which the failure source PSU is installed is under normal conditions. The enclosure fault determination portion 452 corresponds to an example of a “third determination unit”.

The external power supply failure determination portion 453 is notified by the enclosure fault determination portion 452 that the enclosure in which the failure source PSU is installed is under normal conditions. The external power supply failure determination portion 453 measures times taken for periodic voltages such as the maximum and minimum values and 0 V of the input voltage of the external power supply sharing PSU to appear. In this case, the external power supply failure determination portion 453 measures times taken for periodic voltages of the CPSU 101 and the DPSUs 201 in the drive enclosures 21 and 23 to appear. In a case where there is a specific point in the input voltage of the external power supply sharing PSU, the external power supply failure determination portion 453 determines that an abnormality has occurred in the input voltage of the external power supply sharing PSU. The external power supply failure determination portion 453 checks the power interruption detection signal status of the external power supply sharing PSU. The CPSU 101 and the DPSUs 201 in the drive enclosures 21 and 23, which are the external power supply sharing PSUs, correspond to examples of “other power supply units”.

In a case where the external power supply sharing PSU has not output the power interruption detection signal and there is no abnormality in the input voltage information of the external power supply sharing PSU, it is considered that a power supply connected to the failure source PSU does not cause a failure. Accordingly, the external power supply failure determination portion 453 determines that a fault has occurred at the power supply input portion of the failure source PSU, that is, the power supply input portion of the DPSU 201 in the drive enclosure 22. The external power supply failure determination portion 453 notifies the determination result notification unit 406 that a fault has occurred at the power supply input portion of the failure source PSU. In this case, the external power supply failure determination portion 453 notifies the determination result notification unit 406 that a fault has occurred at the power supply input portion of the DPSU 201 in the drive enclosure 22.

On the other hand, in a case where the external power supply sharing PSU has output the power interruption detection signal or there is an abnormality in the input voltage information of the external power supply sharing PSU, it is considered that a power supply connected to the failure source PSU causes a failure. Accordingly, the external power supply failure determination portion 453 determines that a fault has occurred at a power supply connected to the failure source PSU, that is, the external power supply 51 connected to the DPSU 201 in the drive enclosure 22. The external power supply failure determination portion 453 notifies the 406 that a fault has occurred at the power supply connected to the failure source PSU. In this case, the external power supply failure determination portion 453 notifies the determination result notification unit 406 that a fault has occurred at the external power supply 51. The external power supply failure determination portion 453 corresponds to examples of a “first determination unit” and a “determination unit”.

The determination result notification unit 406 receives from the failure isolation unit 405 fault cause determination results acquired by the detection circuit fault determination portion 451, the enclosure fault determination portion 452, and the external power supply failure determination portion 453. The determination result notification unit 406 notifies the administrator of the storage apparatus 1 of the fault cause determination result. For example, the determination result notification unit 406 transmits the fault cause determination result to the host 2 to cause the host 2 to display the fault cause determination result on a monitor connected to the host 2.

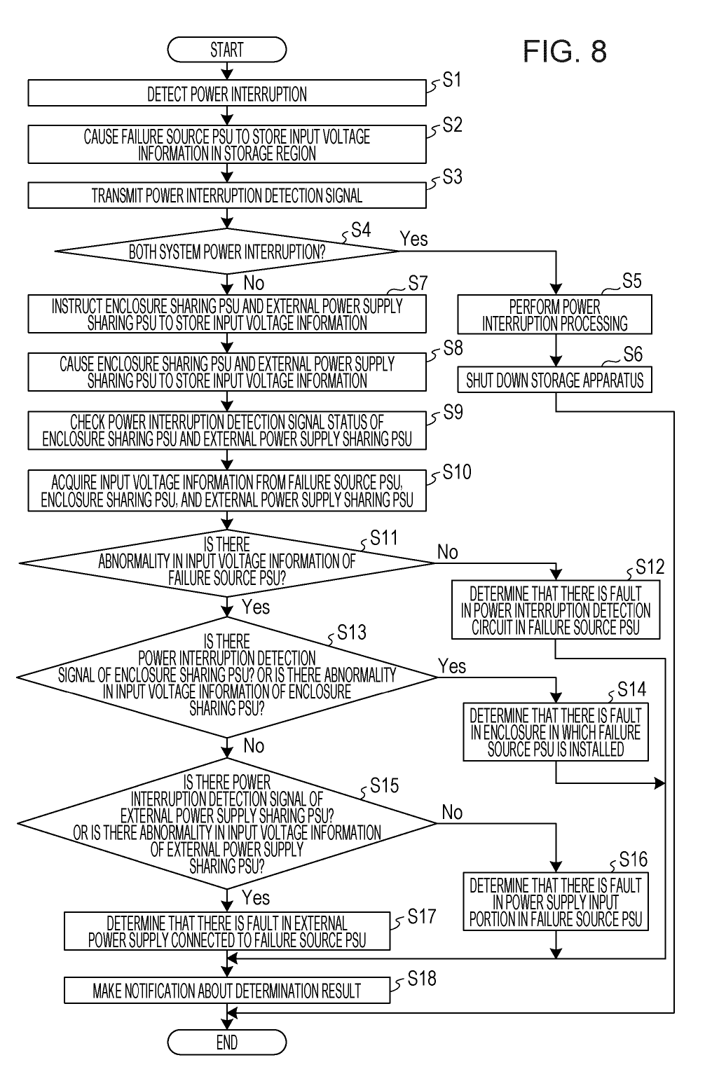

Next, a failure isolation process performed by the storage apparatus 1 according to an embodiment will be described with reference to FIG. 8. FIG. 8 is a flowchart illustrating a failure isolation process performed by a storage apparatus according to an embodiment.

The monitoring control circuit 300 in the failure source PSU detects that the internal voltage has fallen below the abnormality determination threshold value and detects a power interruption (step S1).

The monitoring control circuit 300 in the failure source PSU instructs the input voltage sampling circuit 310 to store the input voltage information in the storage region. Upon receiving the instruction, the input voltage sampling circuit 310 stores the input voltage information in the storage region in the memory 238 (step S2).

Subsequently, the monitoring control circuit 300 in the failure source PSU transmits the power interruption detection signal to the power interruption detection signal receiving unit 401 in the CM 110 (step S3).

The power interruption detection signal receiving unit 401 receives the power interruption detection signal from the failure source PSU, and outputs information about the failure source PSU to the both system power interruption determination unit 402 and the failure isolation unit 405. The both system power interruption determination unit 402 specifies the enclosure sharing PSU based on the PSU configuration information stored in the PSU configuration information storage unit 404. The both system power interruption determination unit 402 checks the power interruption detection signal status of the enclosure sharing PSU using the information transmitted from the power interruption detection signal receiving unit 401 and determines whether a both system power interruption has occurred (step S4).

In a case where it is determined that a both system power interruption has occurred (Yes in step S4), the both system power interruption determination unit 402 performs the power interruption processing (step S5). Subsequently, the both system power interruption determination unit 402 shuts down the storage apparatus 1 (step S6). The failure isolation process ends.

In a case where it is determined that a both system power interruption has not occurred (No in step S4), the both system power interruption determination unit 402 notifies the input voltage collection unit 403 of the information about the failure source PSU and the occurrence of a failure other than the both system power interruption. The both system power interruption determination unit 402 also outputs information about the enclosure sharing PSU to the input voltage collection unit 403. The input voltage collection unit 403 specifies the external power supply sharing PSU based on the PSU configuration information stored in the PSU configuration information storage unit 404. The input voltage collection unit 403 instructs the monitoring control circuits 300 in the enclosure sharing PSU and the external power supply sharing PSU to store the input voltage information (step S7).

The monitoring control circuit 300 in each of the enclosure sharing PSU and the external power supply sharing PSU receives a request for the storage the input voltage information from the input voltage collection unit 403 in the CM 110, and instructs the input voltage sampling circuit 310 to store the input voltage information in the storage region. Upon receiving the instruction, the input voltage sampling circuit 310 in each of the enclosure sharing PSU and the external power supply sharing PSU stores the input voltage information in the storage region in the memory 238 (step S8).

The failure isolation unit 405 checks the power interruption detection signal statuses of the enclosure sharing PSU and the external power supply sharing PSU using the information transmitted from the power interruption detection signal receiving unit 401 (step S9).

The input voltage collection unit 403 requests the monitoring control circuit 300 in each of the failure source PSU, the enclosure sharing PSU, and the external power supply sharing PSU to transmit the input voltage information, and acquires from the monitoring control circuit 300 in each of the failure source PSU, the enclosure sharing PSU, and the external power supply sharing PSU the input voltage information acquired for a predetermined period. The failure isolation unit 405 receives from the input voltage collection unit 403 the pieces of input voltage information acquired for a predetermined period by the failure source PSU, the enclosure sharing PSU, and the external power supply sharing PSU (step S10).

Subsequently, the detection circuit fault determination portion 451 determines whether there is an abnormality in the input voltage information of the failure source PSU (step S11). In a case where there is no abnormality in the input voltage information of the failure source PSU (No in step S11), the detection circuit fault determination portion 451 determines that a fault has occurred at the power interruption detection circuit in the monitoring control circuit 300 in the failure source PSU (step S12). The detection circuit fault determination portion 451 notifies the determination result notification unit 406 that a fault has occurred at the power interruption detection circuit in the monitoring control circuit 300 in the failure source PSU. Subsequently, the process proceeds to step S18.

On the other hand, in a case where there is an abnormality in the input voltage information of the failure source PSU (Yes in step S11), the detection circuit fault determination portion 451 notifies the enclosure fault determination portion 452 that the power interruption detection circuit in the failure source PSU is under normal conditions. Upon being notified that the power interruption detection circuit in the failure source PSU is under normal conditions, the enclosure fault determination portion 452 determines whether there is the power interruption detection signal of the enclosure sharing PSU or there is an abnormality in the input voltage information of the enclosure sharing PSU (step S13). In a case where there is the power interruption detection signal of the enclosure sharing PSU or there is an abnormality in the input voltage information of the enclosure sharing PSU (Yes in step S13), the enclosure fault determination portion 452 determines that a fault has occurred at the enclosure in which the failure source PSU is installed (step S14). The enclosure fault determination portion 452 notifies the determination result notification unit 406 that a fault has occurred at the enclosure in which the failure source PSU is installed. Subsequently, the process proceeds to step S18.

On the other hand, in a case where there is not the power interruption detection signal of the enclosure sharing PSU or there is no abnormality in the input voltage information of the enclosure sharing PSU (No in step S13), the enclosure fault determination portion 452 notifies the external power supply failure determination portion 453 that the enclosure in which the failure source PSU is installed is under normal conditions. Upon being notified that the enclosure in which the failure source PSU is installed is under normal conditions, the external power supply failure determination portion 453 determines whether there is the power interruption detection signal of the external power supply sharing PSU or there is an abnormality in the input voltage information of the external power supply sharing PSU (step S15). In a case where there is not the power interruption detection signal of the external power supply sharing PSU or there is no abnormality in the input voltage information of the external power supply sharing PSU (No in step S15), the external power supply failure determination portion 453 determines that a fault has occurred at the power supply input portion of the failure source PSU (step S16). The external power supply failure determination portion 453 notifies the determination result notification unit 406 that a fault has occurred at the power supply input portion of the failure source PSU. Subsequently, the process proceeds to step S18.

On the other hand, in a case where there is the power interruption detection signal of the external power supply sharing PSU or there is an abnormality in the input voltage information of the external power supply sharing PSU (Yes in step S15), the external power supply failure determination portion 453 determines that a fault has occurred at the external power supply 51 connected to the power supply of the failure source PSU (step S17). A case where a fault has occurred at the external power supply 51 will be described. The external power supply failure determination portion 453 notifies the determination result notification unit 406 that a fault has occurred at the external power supply 51.

The determination result notification unit 406 receives a fault cause determination result from the failure isolation unit 405. The determination result notification unit 406 notifies an administrator of the fault cause determination result (step S18).

As described above, the power supply monitoring device in the storage apparatus according to an embodiment determines whether the both system power interruption has occurred upon receiving the power interruption detection signal transmitted from the failure source PSU. In a case where the power supply monitoring device determines that the both system power interruption has not occurred, the power supply monitoring device performs fault cause isolation using the input voltage information of the failure source PSU and the power interruption detection signal status and input voltage information of each of the enclosure sharing PSU and the external power supply sharing PSU. As a result, in a case where a power interruption other than the both system power interruption has been detected, a failure suspicious part can be easily specified and notified to an administrator. The administrator can perform appropriate maintenance upon the suspicious part. This leads to the appropriate removal of a failure and the increase in the efficiency of a maintenance operation at the time of occurrence of a failure.

In addition, this can avoid the known case where an unbroken PSU is replaced when a power interruption other than the both system power interruption has been detected, and can reduce unnecessary costs of investigating and discarding a normal PSU.

In an embodiment, the detection circuit fault determination portion 451 performs the determination of whether a fault has occurred at the power interruption detection circuit in the failure source PSU, the enclosure fault determination portion 452 performs the determination of whether a fault has occurred at the enclosure in which the failure source PSU is installed, and the external power supply failure determination portion 453 performs the determination of whether a fault has occurred at the power supply input portion of the failure source PSU. However, all of these determinations do not necessarily have to be performed. Fault cause isolation may be performed by performing any one of them or some of them in combination. For example, in a case where it is determined which of the external power supply 51 and the failure source PSU causes a failure, the external power supply failure determination portion 453 performs fault cause isolation and the other determinations do not necessarily have to be performed. Even in this case, since a suspicious part can be more precisely specified than before, the efficiency of a maintenance operation can be increased.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A power supply monitoring device comprising:
a memory; and
a first processor coupled to the memory and configured to:
receive an abnormality occurrence notification from an abnormality source power supply unit that is one of a plurality of power supply units each including a second processor and coupled to one of a plurality of external power supplies,
upon reception of an abnormality occurrence notification from a specific power supply unit, acquire input voltages of other power supply units coupled to a specific external power supply coupled to the specific power supply unit and perform a first determination of whether a failure has occurred at the specific power supply unit based on the input voltages of the other power supply units and abnormality occurrence notifications received from the other power supply units, and
make a notification about a result of the first determination.

2. The power supply monitoring device according to claim 1, wherein the first processor is further configured to:
when an abnormality has occurred in the input voltages of the other power supply units or an abnormality occurrence notification is received from any one of the other power supply units, the first processor determines that a failure has occurred at the specific external power supply; and
when an abnormality does not occur in the input voltages of the other power supply units and an abnormality occurrence notification is not received from any of the other power supply units, the first processor determines that a failure has occurred at the specific power supply unit.

3. The power supply monitoring device according to claim 1, wherein the first processor is further configured to
when an abnormality occurrence notification has been received from the specific power supply unit, acquire an input voltage of the specific power supply unit, and determine that a failure has occurred at a detection circuit for detecting an abnormality at the specific power supply unit when there is no abnormality in the input voltage of the specific power supply unit.

4. The power supply monitoring device according to claim 1, wherein the first processor is further configured to
when an abnormality occurrence notification has been received from the specific power supply unit, acquire an input voltage of a redundant power supply unit that corresponds to the specific power supply unit and is installed in an enclosure along with the specific power supply unit, and determine that an abnormality has occurred at the enclosure when there is no abnormality in the input voltage of the redundant power supply unit and when an abnormality occurrence notification has been received from the redundant power supply unit.

5. A storage apparatus comprising:
a memory;
a first processor coupled to the memory and configured to control reading and writing of data from and to the memory and supply of power to the memory; and
a plurality of power supply units each coupled to one of a plurality of external power supplies and each configured to receive power from one of the plurality of external power supplies which is coupled to the power supply unit and supply the power to the memory or the first processor, the power supply unit including a second processor configured to, when an abnormality has occurred at an input voltage supplied from the external power supply coupled to the power supply unit, notify the first processor that the abnormality has occurred, wherein
the first processor is configured to:
receive an abnormality occurrence notification from an abnormality source power supply unit that is one of the plurality of power supply units,
when an abnormality occurrence notification has been received from a specific power supply unit, acquire input voltages of other power supply units coupled to a specific external power supply coupled to the specific power supply unit, and perform a determination of whether a failure has occurred at the specific power supply unit based on the input voltages of the other power supply units and abnormality occurrence notifications received from the other power supply units, and
make a notification about a result of the determination.

6. The storage apparatus according to claim 5, wherein:
when an abnormality has occurred in the input voltages of the other power supply units or an abnormality occurrence notification is received from any one of the other power supply units, the first processor determines that a failure has occurred at the specific external power supply, and
when an abnormality does not occur in the input voltages of the other power supply units and an abnormality occurrence notification is not received from any of the other power supply units, the first processor determines that a failure has occurred at the specific power supply unit.

7. The storage apparatus according to claim 5, wherein the first processor is further configured to
when an abnormality occurrence notification has been received from the specific power supply unit, acquire an input voltage of the specific power supply unit, and determine that a failure has occurred at a detection circuit for detecting an abnormality at the specific power supply unit when there is no abnormality in the input voltage of the specific power supply unit.

8. The storage apparatus according to claim 5, wherein the first processor is further configured to
when an abnormality occurrence notification has been received from the specific power supply unit, acquire an input voltage of a redundant power supply unit that corresponds to the specific power supply unit and is installed in an enclosure along with the specific power supply unit, and determine that an abnormality has occurred at the enclosure when there is no abnormality in the input voltage of the redundant power supply unit and when an abnormality occurrence notification has been received from the redundant power supply unit.

9. A power supply monitoring method comprising:
receiving, by the power supply monitoring device, an abnormality occurrence notification from a specific power supply unit that is one of a plurality of power supply units each coupled to one of a plurality of external power supplies;
acquiring, by the power supply monitoring device, input voltages of other power supply units coupled to a specific external power supply coupled to the specific power supply unit; and
performing, by the power supply monitoring device, a first determination of whether a failure has occurred at the specific power supply unit based on the input voltages of the other power supply units and the abnormality occurrence notifications received from the other power supply units.

10. The power supply monitoring method according to claim 9, further comprising:
when an abnormality has occurred in the input voltages of the other power supply units or an abnormality occurrence notification is received from any one of the other power supply units, determine that a failure has occurred at the specific external power supply, and
when an abnormality does not occur in the input voltages of the other power supply units and an abnormality occurrence notification is not received from any of the other power supply units, determine that a failure has occurred at the specific power supply unit.

11. The power supply monitoring method according to claim 9, further comprising:
when an abnormality occurrence notification has been received from the specific power supply unit, acquire an input voltage of the specific power supply unit, and determine that a failure has occurred at a detection circuit for detecting an abnormality at the specific power supply unit when there is no abnormality in the input voltage of the specific power supply unit.

12. The power supply monitoring method according to claim 9, further comprising:
when an abnormality occurrence notification has been received from the specific power supply unit, acquire an input voltage of a redundant power supply unit that corresponds to the specific power supply unit and is installed in an enclosure along with the specific power supply unit, and determine that an abnormality has occurred at the enclosure when there is no abnormality in the input voltage of the redundant power supply unit and when an abnormality occurrence notification has been received from the redundant power supply unit.
